(19) United States
(12) Patent Application Publication
(10) Pub. No.: US 2016/0037681 A1
(43) Pub. Date: Feb. 4, 2016

(54) MOBILE TERMINAL

(71) Applicants: LG ELECTRONICS INC., Seoul (KR); KOREA UNIVERSITY RESEARCH & BUSINESS FOUNDATION, Seoul (KR)

(72) Inventors: Joseph LEE, Seoul (KR); Wonkee AHN, Seoul (KR); Dongsoo JANG, Seoul (KR); Eunji LEE, Seoul (KR); Yonghee JANG, Gunpo-si (KR); Kyungui PARK, Seoul (KR); Yongchan KIM, Seoul (KR)

(73) Assignees: KOREA UNIVERSITY RESEARCH & BUSINESS FOUNDATION, Seoul (KR); LG ELECTRONICS INC., Seoul (KR)

(21) Appl. No.: 14/776,795

(22) PCT Filed: Aug. 21, 2013
(86) PCT No.: PCT/KR2013/007487

§ 371 Date: Sep. 15, 2015

(30) Foreign Application Priority Data
May 7, 2013 (KR) 10-2013-0051246

(51) Int. Cl. H05K 7/20; H04M 1/02

(52) U.S. Cl. CPC H05K 7/20272; H04M 1/0254

(57) ABSTRACT

There is disclosed a mobile terminal including a case comprising a control portion provided therein, a display coupled to the case, a main circuit board mounted in a predetermined portion of the control portion, a heat exchanger having a portion arranged adjacent to the main circuit board, with a plurality of micro-paths extended from the portion to the other portion, each of the micro-paths connected to a neighboring one to form a closed loop, and a working fluid configured to absorb heat in the portion and emit the heat in the other portion, to be liquefied, the working fluid configured to vibrate along the micro-paths, wherein a gaseous state working fluid and a liquid state working fluid are mixed intermittently.

### TECHNICAL FIELD

The present invention relates to a mobile terminal that includes a heat exchanger configured to radiate the heat generated in the mobile terminal.

### BACKGROUND ART

Terminals can be classified into mobile terminals and stationary terminals. In addition, the mobile terminals can be further classified into handheld terminals and vehicle mount terminals.

Further, a mobile terminal can perform various functions such as data and voice communications, capturing images and video via a camera, recording audio, playing music files and outputting music via a speaker system, and displaying images and video on a display.

Various components are mounted in such a mobile terminal to realize the various functions. When the components are put into operation sequentially or simultaneously, a lot of heat is generated. In addition, the mobile terminal is not used only for one function simply but for the various functions, such that use time of the mobile terminal may increase. Accordingly, there is a disadvantage that the temperature of the mobile terminal rises continuously.

If the temperature of the mobile terminal rises, it will be difficult for a user to hold and use the mobile terminal in the hand. The rise of the mobile terminal temperature might affect functions of the electronic components mounted in the mobile terminal and a heat radiation function of the heat generated in the mobile terminal is related to the other functions of the mobile terminal.

### DISCLOSURE OF INVENTION

### Technical Problem

An object of the present invention is to provide a mobile terminal that includes a heat exchanger configured to absorb and diffuse the heat generated in a portion of the mobile terminal to the other opposite portion, only to enhance heat radiation efficiency of the mobile terminal.

Additional advantages, objects, and features of the disclosure will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

### Solution to Problem

To achieve these objects and other advantages and in accordance with the purpose of the invention, as embodied and broadly described herein, a mobile terminal includes a mobile terminal includes a case comprising a control portion provided therein; a display coupled to the case; a main circuit board mounted in a predetermined portion of the control portion; a heat exchanger having a portion arranged adjacent to the main circuit board, with a plurality of micro-paths extended from the portion to the other portion, each of the micro-paths connected to a neighboring one to form a closed loop; and a working fluid configured to absorb heat in the portion and emit the heat in the other portion, to be liquefied, the working fluid configured to vibrate along the micro-paths, wherein a gaseous state working fluid and a liquid state working fluid are mixed intermittently.

The heat exchanger may be a middle frame configured to support a back surface of the display.

The heat exchanger may be a back cover detachably coupled to a back surface of the case.

The mobile terminal may further include a heat exchanging portion where the micro-paths of the heat exchanger are formed; and an injection molded portion coupled to the heat exchanging portion in a double injection molding method.

The micro-paths may form a serpentine structure and further include a connection path configured to connect both ends of the serpentine structure micro-paths.

The portion may be a lower portion of the mobile terminal and the other portion may be an upper portion of the mobile terminal, and the micro-paths may be formed in a vertical direction.

The micro-paths may be obliquely formed in a diagonal direction with respect to the mobile terminal.

A cross section of a micro-path may be rectangular.

A hydraulic diameter of the micro-path may be 500 μm or more and 1000 μm or less.

The working fluid may be injected in the micro-paths by 30% or more and 70% or more of the volume.

A boiling point of the working fluid may be 40° C. or more and 70° C. or less.

The working fluid may be perfluorocarbon (PFCs) compound.

The mobile may further include a oscillator configured to apply vibration to the heat exchanger, wherein the oscillator is driven when the temperature of the mobile terminal is an operation temperature of the heat exchanger or more.

The oscillator may be driven at predetermined intervals intermittently.

### Advantageous Effects of Invention

According to at least one embodiments of the present invention, the mobile terminal 100 including the heat exchanger 200 may use a convection method instead of the conventional conduction type heat radiation method and enhance the heat radiation efficiency.

Especially, the heat exchanger 200 including the micro-paths 201 having the hydraulic diameter of approximately 700 μm may be provided. When injecting 50% of FC-72 as the working fluid 210, the thermal resistance can be lowered by approximately 50%, compared with the graphite sheet. Accordingly, the heat radiation efficiency can be increased by approximately 150% or more.

Furthermore, the heat exchanger may be functioned as the middle frame configured to support the display as well as the heat radiating function. When using the heat exchanger according to the present invention, instead of the middle frame, the heat radiation efficiency may be enhanced, without increasing the number of components.

It is to be understood that both the foregoing general description and the following detailed description of the embodiments are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram of a mobile terminal according to one embodiment of the present invention;

FIG. 2 is a front perspective diagram of a mobile terminal according to one embodiment of the present invention;

FIG. 3 is an exploded perspective diagram of a mobile terminal according to one embodiment of the present invention;

FIG. 4 is a diagram illustrating thermal gradient of a conventional mobile terminal;

FIG. 5 is a perspective diagram illustrating a heat exchanger according to one embodiment of the present invention;

FIG. 6 is a longitudinal sectional diagram of the heat exchanger according to one embodiment of the present invention;

FIG. 7 is a horizontal sectional diagram of the heat exchanger according to one embodiment of the present invention;

FIG. 8 is a sectional diagram illustrating that a working fluid filled in the heat exchanger according to one embodiment of the present invention is flowing;

FIG. 9 is a graph illustrating thermal resistance based on the size of a micro-path provided in the heat exchanger, a type of a working fluid and an injection degree of the working fluid according to one embodiment of the present invention;

FIG. 10 is a longitudinal sectional diagram of a heat exchanger according to another embodiment of the present invention; and

FIG. 11 is a graph illustrating thermal resistance based on whether to use an oscillator of the mobile terminal according to the embodiment of the present invention.

### MODE FOR THE INVENTION

In the following detailed description, reference is made to the accompanying drawing figures which form a part hereof, and which show by way of illustration various embodiments.

As used herein, the suffixes module , unit and part are used for elements in order to facilitate the disclosure only. Therefore, significant meanings or roles are not given to the suffixes themselves and it is understood that the module , unit and part can be used together or interchangeably.

The various features described herein may be applicable to a various types of mobile terminals. Examples of such terminals may include mobile phones, user equipments, smart phones, digital broadcast receivers, personal digital assistants, laptop computers, portable multimedia players (PMP), navigators and the like.

Yet, it is apparent to those skilled in the art that a configuration according to an embodiment disclosed in this specification may also be applicable to a fixed terminal such as a digital TV, a desktop computer and the like as well as a mobile terminal.

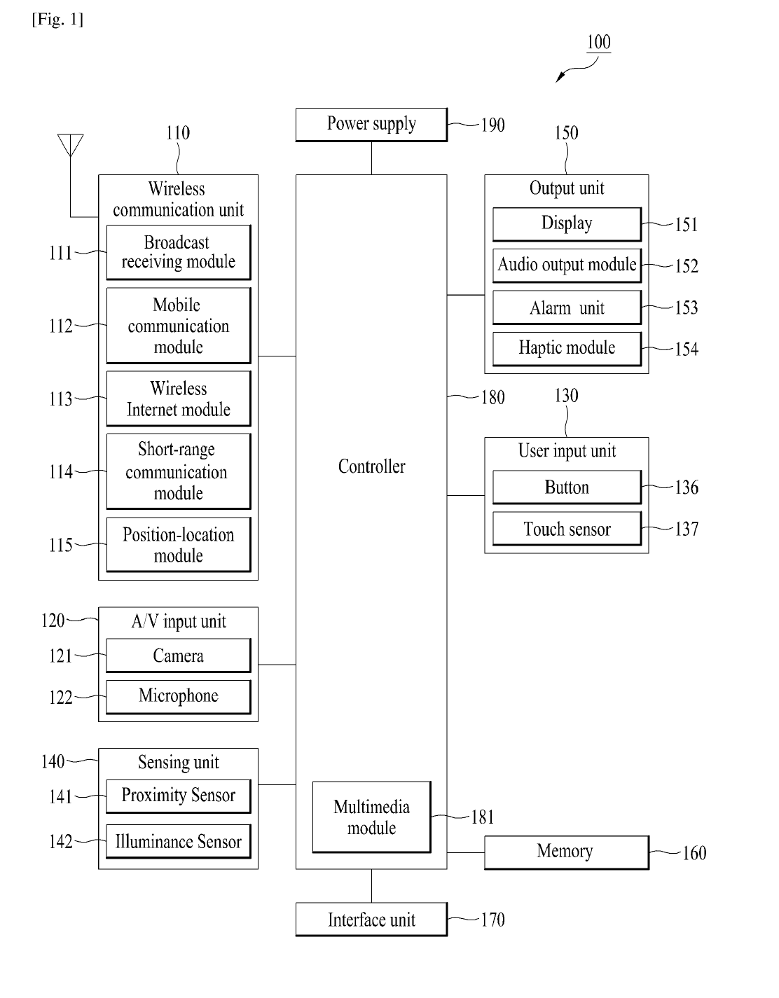

FIG. 1 is a block diagram of a mobile terminal 100 in accordance with an embodiment as broadly described herein. The mobile terminal 100 may include a wireless communication unit 110, an A/V (audio/video) input unit 120, a user input unit 130, a sensing unit 140, an output unit 150, a memory 160, an interface unit 170, a controller 180, a power supply unit 190 and the like. FIG. 1 shows the mobile terminal 100 having various components, but it is understood that implementing all of the illustrated components is not a requirement. Greater or fewer components may alternatively be implemented.

In the following description, the above elements of the mobile terminal 100 are explained in sequence.

First of all, the wireless communication unit 110 typically includes one or more components which permits wireless communication between the mobile terminal 100 and a wireless communication system or network within which the mobile terminal 100 is located. For instance, the wireless communication unit 110 can include a broadcast receiving module 111, a mobile communication module 112, a wireless internet module 113, a short-range communication module 114, a position-location module 115 and the like.

The broadcast receiving module 111 receives a broadcast signal and/or broadcast associated information from an external broadcast managing server via a broadcast channel. The broadcast channel may include a satellite channel and a terrestrial channel. At least two broadcast receiving modules 111 can be provided to the mobile terminal 100 in pursuit of simultaneous receptions of at least two broadcast channels or broadcast channel switching facilitation.

The broadcast managing server generally refers to a server which generates and transmits a broadcast signal and/or broadcast associated information or a server which is provided with a previously generated broadcast signal and/or broadcast associated information and then transmits the provided signal or information to a terminal. The broadcast signal may be implemented as a TV broadcast signal, a radio broadcast signal, and a data broadcast signal, among others. If desired, the broadcast signal may further include a broadcast signal combined with a TV or radio broadcast signal.

The broadcast associated information includes information associated with a broadcast channel, a broadcast program, a broadcast service provider, etc. And, the broadcast associated information can be provided via a mobile communication network. In this case, the broadcast associated information can be received by the mobile communication module 112.

The broadcast associated information can be implemented in various forms. For instance, broadcast associated information may include an electronic program guide (EPG) of digital multimedia broadcasting (DMB) and electronic service guide (ESG) of digital video broadcast-handheld (DVB-H).

The broadcast receiving module 111 may be configured to receive broadcast signals transmitted from various types of broadcast systems. By nonlimiting example, such broadcasting systems include digital multimedia broadcasting-terrestrial (DMB-T), digital multimedia broadcasting-satellite (DMB-S), digital video broadcast-handheld (DVB-H), Convergence of Broadcasting and Mobile Service(DVB-CBMS), Open Mobile Alliance-BroadCAST(OMA-BCAST), China Multimedia Mobile Broadcasting(CMMB), Mobile Broadcasting Business Management System(MBBMS), the data broadcasting system known as media forward link only (MediaFLO) and integrated services digital broadcast-terrestrial (ISDB-T). Optionally, the broadcast receiving module 111 can be configured suitable for other broadcasting systems as well as the above-explained digital broadcasting systems.

The broadcast signal and/or broadcast associated information received by the broadcast receiving module 111 may be stored in a suitable device, such as a memory 160.

The mobile communication module 112 transmits/receives wireless signals to/from one or more network entities (e.g., base station, external terminal, server, etc.) via a mobile network such as GSM (Gobal System for Mobile communications), CDMA (Code Division Multiple Access), WCDMA (Wideband CDMA) and so on. Such wireless signals may represent audio, video, and data according to text/multimedia message transmission and reception, among others.

The wireless internet module 113 supports Internet access for the mobile terminal 100. This module may be internally or externally coupled to the mobile terminal 100. In this case, the wireless Internet technology can include WLAN (Wireless LAN) (Wi-Fi), Wibro (Wireless broadband), Wimax (World Interoperability for Microwave Access), HSDPA (High Speed Downlink Packet Access), GSM, CDMA, WCDMA, LTE (Long Term Evolution) etc.

Wireless internet access by Wibro, HSPDA, GSM, CDMA, WCDMA, LTE or the like is achieved via a mobile communication network. In this aspect, the wireless internet module 113 configured to perform the wireless internet access via the mobile communication network can be understood as a sort of the mobile communication module 112.

The short-range communication module 114 facilitates relatively short-range communications. Suitable technologies for implementing this module include radio frequency identification (RFID), infrared data association (IrDA), ultra-wideband (UWB), as well at the networking technologies commonly referred to as Bluetooth and ZigBee, to name a few.

The position-location module 115 identifies or otherwise obtains the location of the mobile terminal 100. If desired, this module may be implemented with a global positioning system (GPS) module. According to the current technology, the GPS module 115 is able to precisely calculate current 3-dimensional position information based on at least one of longitude, latitude and altitude and direction (or orientation) by calculating distance information and precise time information from at least three satellites and then applying triangulation to the calculated information. Currently, location and time information are calculated using three satellites, and errors of the calculated location position and time information are then amended using another satellite. Besides, the GPS module 115 is able to calculate speed information by continuously calculating a real-time current location.

Referring to FIG. 1, the audio/video (A/V) input unit 120 may be configured to provide audio or video signal input to the mobile terminal 100. As shown, the A/V input unit 120 includes a camera 121 and a microphone 122. The camera 121 receives and processes image frames of still pictures or video, which are obtained by an image sensor in a video call mode or a photographing mode. In addition, the processed image frames can be displayed on the display 151 of the output unit 150.

The image frames processed by the camera 121 can be stored in the memory 160 or can be externally transmitted via the wireless communication unit 110. Optionally, at least two cameras 121 can be provided to the mobile terminal 100 according to environment of usage.

The microphone 122 receives an external audio signal while the portable device is in a particular mode, such as phone call mode, recording mode and voice recognition. This audio signal is processed and converted into electric audio data. The processed audio data is transformed into a format transmittable to a mobile communication base station via the mobile communication module 112 in case of a call mode. The microphone 122 may include assorted noise removing algorithms to remove noise generated in the course of receiving the external audio signal.

The user input unit 130 may generate input data responsive to user manipulation of an associated input device or devices. Examples of such devices include a button 136 provided to front/rear/lateral side of the mobile terminal 100 and a touch sensor (pressure sensitive touch/ capacitive touch) 137 and may further include a key pad, a dome switch, a jog wheel, a jog switch and the like.

The sensing unit 140 may provide sensing signals for controlling operations of the mobile terminal 100 using status measurements of various aspects of the mobile terminal 100. For instance, the sensing unit 140 may detect an open/close status of the mobile terminal 100, relative positioning of components (e.g., a display and keypad) of the mobile terminal 100, a change of position of the mobile terminal 100 or a component of the mobile terminal 100, a presence or absence of user contact with the mobile terminal 100, orientation or acceleration/deceleration of the mobile terminal 100. By nonlimiting example, such a sensing unit 140 may include, a gyro sensor, an acceleration sensor, a geomagnetic sensor and the like.

As an example, consider the mobile terminal 100 being configured as a slide-type mobile terminal. In this configuration, the sensing unit 140 may sense whether a sliding portion of the mobile terminal is open or closed. Other examples include the sensing unit 140 sensing the presence or absence of power provided by the power supply 190, the presence or absence of a coupling or other connection between the interface unit 170 and an external device. In addition, the sensing unit 140 may include a proximity sensor 141.

The output unit 150 may generate outputs relevant to the senses of sight, hearing, touch and the like. The output unit 150 includes the display 151, an audio output module 152, an alarm unit 153, and a haptic module 154 and the like.

The display 151 may be implemented to visually display (output) information associated with the mobile terminal 100. For instance, if the mobile terminal is operating in a phone call mode, the display may provide a user interface (UI) or graphical user interface (GUI) which includes information associated with placing, conducting, and terminating a phone call. As another example, if the mobile terminal 100 is in a video call mode or a photographing mode, the display 151 may additionally or alternatively display images which are associated with these modes, the UI or the GUI.

The display 151 may be implemented using known display technologies including, for example, a liquid crystal display (LCD), a thin film transistor-liquid crystal display (TFT-LCD), an organic light-emitting diode display (OLED), a flexible display and a three-dimensional display. The mobile terminal 100 may include one or more of such displays.

Some of the above displays can be implemented in a transparent or optical transmittable type, which can be named a transparent display. As a representative example for the transparent display, there is TOLED (transparent OLED) or the like. A rear configuration of the display 151 can be implemented in the optical transmittive type as well. In this configuration, a user is able to see an object in rear of a terminal body via the area occupied by the display 151 of the terminal body.

At least two displays 151 may be provided to the mobile terminal 100 in accordance with the implemented configuration of the mobile terminal 100. For instance, a plurality of displays can be arranged on a single face of the mobile terminal 100 in a manner of being spaced apart from each other or being built in one body. Alternatively, a plurality of displays can be arranged on different faces of the mobile terminal 100.

In case that the display 151 and the touch sensor 137 configures a mutual layer structure (hereinafter called touch screen), it is able to use the display 151 as an input device as well as an output device. In this case, the touch sensor may be configured as a touch film, a touch sheet, a touchpad or the like.

The touch sensor 137 can be configured to convert a pressure applied to a specific portion of the display 151 or a variation of a capacitance generated from a specific portion of the display 151 to an electric input signal. Moreover, it is able to configure the touch sensor 137 to detect a pressure of a touch as well as a touched position or size.

If a touch input is made to the touch sensor 137, signal(s) corresponding to the touch is transferred to a touch controller. The touch controller processes the signal(s) and then transfers the processed signal(s) to the controller 180. Therefore, the controller 180 is able to know whether a prescribed portion of the display 151 is touched.

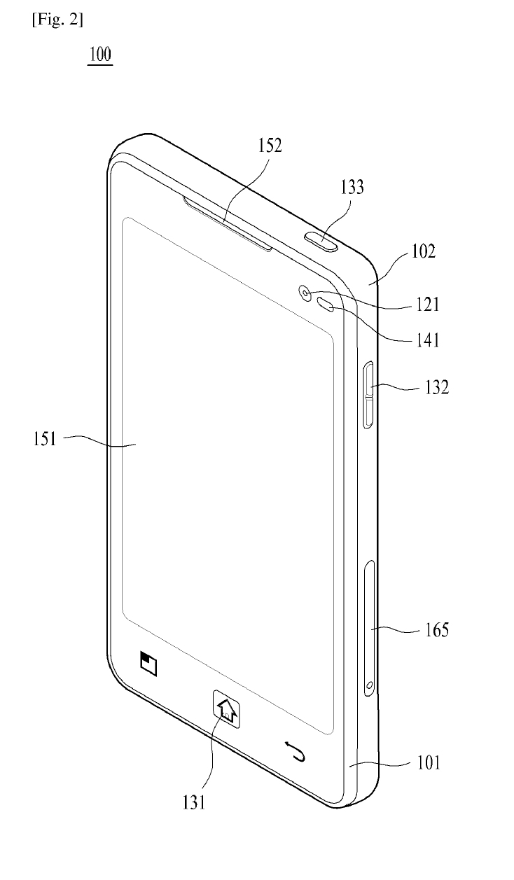

Referring to FIGS. 1 and 2, a proximity sensor 141 can be provided to an internal area of the mobile terminal 100 enclosed by the touchscreen or around the touchscreen. The proximity sensor 141 is the sensor that detects a presence or non-presence of an object approaching a prescribed detecting surface or an object existing around the proximity sensor using an electromagnetic field strength or infrared ray without mechanical contact. Hence, the proximity sensor has durability longer than that of a contact type sensor and also has utility wider than that of the contact type sensor.

The proximity sensor 141 can include one of a transmittive photoelectric sensor, a direct reflective photoelectric sensor, a mirror reflective photoelectric sensor, a radio frequency oscillation proximity sensor, an electrostatic capacity proximity sensor, a magnetic proximity sensor, an infrared proximity sensor and the like. In case that the touchscreen includes the electrostatic capacity proximity sensor, it is configured to detect the proximity of a pointer using a variation of electric field according to the proximity of the pointer. In this case, the touchscreen (touch sensor) can be classified as the proximity sensor.

For clarity and convenience of the following description, as a pointer becomes proximate to a touchscreen without coming into contact with the touchscreen, if the pointer is perceived as situated over the touchscreen, such an action shall be named proximity touch. If a pointer actually comes into contact with a touchscreen, such an action shall be named contact touch. A proximity-touched position over the touchscreen with the pointer may mean a position at which the pointer vertically opposes the touchscreen when the touchscreen is proximity-touched with the pointer.

The proximity sensor 141 detects a proximity touch and a proximity touch pattern (e.g., a proximity touch distance, a proximity touch duration, a proximity touch position, a proximity touch shift state, etc.). In addition, information corresponding to the detected proximity touch action and the detected proximity touch pattern can be outputted to the touchscreen.

The audio output module 152 functions in various modes including a call-receiving mode, a call-placing mode, a recording mode, a voice recognition mode, a broadcast reception mode and the like to output audio data which is received from the wireless communication unit 110 or is stored in the memory 160. During operation, the audio output module 152 outputs audio relating to a particular function (e.g., call received, message received, etc.). The audio output module 152 is often implemented using one or more speakers, buzzers, other audio producing devices, and combinations thereof.

The alarm unit 153 is output a signal for announcing the occurrence of a particular event associated with the mobile terminal 100. Typical events include a call received event, a message received event and a touch input received event. The alarm unit 153 is able to output a signal for announcing the event occurrence by way of vibration as well as video or audio signal. The video or audio signal can be output via the display 151 or the audio output unit 152. Hence, the display 151 or the audio output module 152 can be regarded as a part of the alarm unit 153.

The haptic module 154 generates various tactile effects that can be sensed by a user. Vibration is a representative one of the tactile effects generated by the haptic module 154. Strength and pattern of the vibration generated by the haptic module 154 are controllable. For instance, different vibrations can be output in a manner of being synthesized together or can be output in sequence.

The haptic module 154 is able to generate various tactile effects as well as the vibration. For instance, the haptic module 154 generates the effect attributed to the arrangement of pins vertically moving against a contact skin surface, the effect attributed to the injection/suction power of air though an injection/suction hole, the effect attributed to the skim over a skin surface, the effect attributed to the contact with electrode, the effect attributed to the electrostatic force, the effect attributed to the representation of hold/cold sense using an endothermic or exothermic device and the like.

The haptic module 154 can be implemented to enable a user to sense the tactile effect through a muscle sense of finger, arm or the like as well as to transfer the tactile effect through a direct contact. Optionally, at least two haptic modules 154 can be provided to the mobile terminal 100 in accordance with the corresponding configuration type of the mobile terminal 100.

The memory unit 160 is generally used to store various types of data to support the processing, control, and storage requirements of the mobile terminal 100. Examples of such data include program instructions for applications operating on the mobile terminal 100, contact data, phonebook data, messages, audio, still pictures (or photo), moving pictures, etc. In addition, a recent use history or a cumulative use frequency of each data (e.g., use frequency for each phonebook, each message or each multimedia) can be stored in the memory unit 160. Moreover, data for various patterns of vibration and/or sound output in case of a touch input to the touchscreen can be stored in the memory unit 160.

The memory 160 may be implemented using any type or combination of suitable volatile and non-volatile memory or storage devices including hard disk, random access memory (RAM), static random access memory (SRAM), electrically erasable programmable read-only memory (EEPROM), erasable programmable read-only memory (EPROM), programmable read-only memory (PROM), read-only memory (ROM), magnetic memory, flash memory, magnetic or optical disk, multimedia card micro type memory, card-type memory (e.g., SD memory, XD memory, etc.), or other similar memory or data storage device. In addition, the mobile terminal 100 is able to operate in association with a web storage for performing a storage function of the memory 160 on Internet.

The interface unit 170 is often implemented to couple the mobile terminal 100 with external devices. The interface unit 170 receives data from the external devices or is supplied with the power and then transfers the data or power to the respective elements of the mobile terminal 100 or enables data within the mobile terminal 100 to be transferred to the external devices.

The interface unit 170 may be configured using a wired/wireless headset port, an external charger port, a wired/wireless data port, a memory card port, a port for coupling to a device having an identity module, audio input/output ports, video input/output ports, an earphone port and/or the like.

The identity module is the chip for storing various kinds of information for authenticating a use authority of the mobile terminal 100 and can include User Identify Module (UIM), Subscriber Identify Module (SIM), Universal Subscriber Identity Module (USIM) and/or the like. A device having the identity module (hereinafter called identity device) can be manufactured as a smart card. Therefore, the identity device is connectible to the mobile terminal 100 via the corresponding port.

When the mobile terminal 100 is connected to an external cradle, the interface unit 170 becomes a passage for supplying the mobile terminal 100 with a power from the cradle or a passage for delivering various command signals input from the cradle by a user to the mobile terminal 100. Each of the various command signals input from the cradle or the power can operate as a signal enabling the mobile terminal 100 to recognize that it is correctly loaded in the cradle.

The controller 180 may control the overall operations of the mobile terminal 100. For example, the controller 180 may performs the control and processing associated with voice calls, data communications, video calls, etc. The controller 180 may include a multimedia module 181 that provides multimedia playback. The multimedia module 181 may be configured as part of the controller 180, or implemented as a separate component.

Moreover, the controller 180 is able to perform a pattern (or image) recognizing process for recognizing a writing input and a picture drawing input carried out on the touchscreen as characters or images, respectively.

The power supply unit 190 provides power required by the various components for the mobile terminal 100. The power may be internal power, external power, or combinations thereof.

A battery may include a built-in rechargeable battery and may be detachably attached to the terminal body for a charging and the like. A connecting port may be configured as one example of the interface 170 via which an external charger for supplying a power of a battery charging is electrically connected.

Various embodiments described herein may be implemented in a computer-readable medium using, for example, computer software, hardware, or some combination thereof.

For a hardware implementation, the embodiments described herein may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a selective combination thereof. Such embodiments may also be implemented by the controller 180.

For a software implementation, the embodiments described herein may be implemented with separate software modules, such as procedures and functions, each of which perform one or more of the functions and operations described herein. The software codes can be implemented with a software application written in any suitable programming language and may be stored in memory such as the memory 160, and executed by a controller or processor, such as the controller 180.

Next, FIG. 2 is a front perspective diagram of a mobile terminal according to one embodiment of the present invention.

The mobile terminal 100 shown in the drawing has a bar type terminal body. Yet, the mobile terminal 100 may be implemented in a variety of different configurations. Examples of such configurations include folder-type, slide-type, rotational-type, swing-type and combinations thereof. For clarity, further disclosure will primarily relate to a bar-type mobile terminal 100. However such teachings apply equally to other types of mobile terminals.

Referring to FIG. 2, the mobile terminal 100 includes a case 101, 102, 103 configuring an exterior thereof. In the present embodiment, the case can be divided into a front case 101 and a rear case 102. Various electric/electronic parts are loaded in a space provided between the front and rear cases 101 and 102.

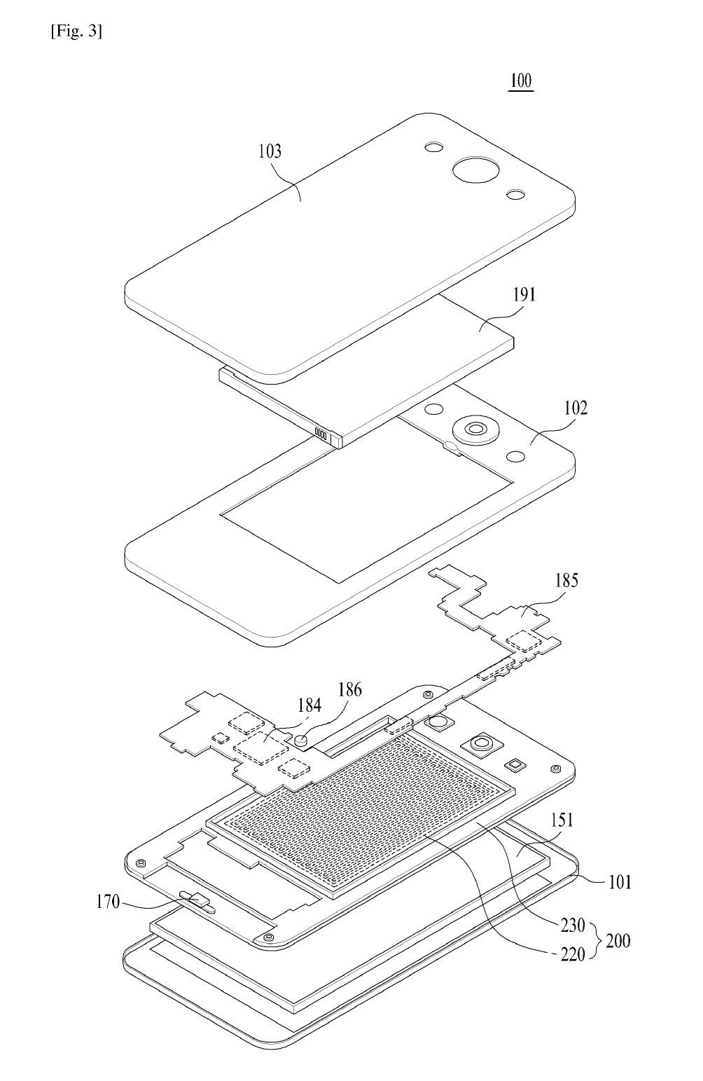

Occasionally, electronic components can be mounted on a surface of the rear case 102. The electronic part mounted on the surface of the rear case 102 may include such a detachable part such as a battery, a USIM card, a memory card and the like. In doing so, the rear case 102 may further include a backside cover 103 (see FIG. 3) configured to cover the surface of the rear case 102. In particular, the backside cover 103 has a detachable configuration for the user s convenience. If the backside cover 103 is detached from the rear case 102, the surface of the rear case 102 is exposed.

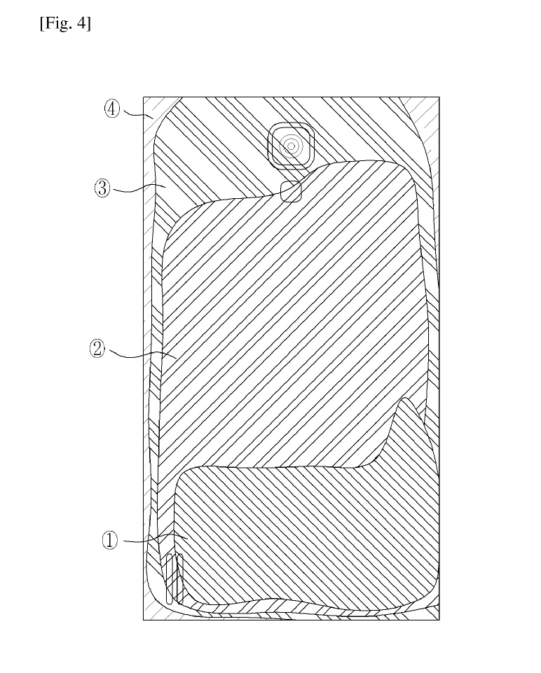

Referring to FIG. 3, if the backside cover 103 is attached to the rear case 102, a lateral side of the rear case 102 may be exposed in part. If a size of the backside cover 103 is decreased, a rear side of the rear case 102 may be exposed in part. If the backside cover 103 covers the whole rear side of the rear case 102, it may include an opening 103 (see FIG. 4) configured to expose a camera 121 or an audio output unit 152 externally.

The cases 101, 102 and 103 can be formed by injection molding of synthetic resin or can be formed of metal substance such as stainless steel (STS), titanium (Ti) or the like for example.

A display 151, an audio output unit 152, a camera 121, user input units 130/131 and 132, a microphone 122, an interface 170 and the like can be provided to the case 101 or 102.

The display 151 occupies most of a main face of the front case 101. The audio output unit 152 and the camera 121 are provided to an area adjacent to one of both end portions of the display 151, while the user input unit 131 and the microphone 122 are provided to another area adjacent to the other end portion of the display 151. The user input unit 132 and the interface 170 can be provided to lateral sides of the front and rear cases 101 and 102.

The input unit 130 is manipulated to receive a command for controlling an operation of the terminal 100. And, the input unit 130 is able to include a plurality of manipulating units 131 and 132. The manipulating units 131 and 132 can be named a manipulating portion and may adopt any mechanism of a tactile manner that enables a user to perform a manipulation action by experiencing a tactile feeling.

Content input by the first or second manipulating unit 131 or 132 can be diversely set. For instance, such a command as start, end, scroll and the like is input to the first manipulating unit 131. In addition, a command for a volume adjustment of sound output from the audio output unit 152 and the like can be input to the second manipulating unit 132, a command for a switching to a touch recognizing mode of the display 151 and the like can be input to the third manipulating unit 133.

A button type is configured to recognize a pressure applied by a user to each of the manipulation units 131, 132 and 133. If a touch sensor is provided to each of the manipulation units 131, 132 and 133 in addition to the display unit 151, a user s command can be inputted by a user s touch.

FIG. 3 is an exploded perspective diagram of the mobile terminal according to one embodiment of the present invention. In FIG. 3 are shown a back cover 103, a rear case 102, a main circuit board 185, a heat exchanger 200, a display 151 and a front case 101.

The front case 101 and the rear case 102 are coupled to each other and a control portion is formed there between. Electronic components are mounted in the control portion. Specifically, various electronic components including the main circuit board 185, the heat exchanger 200 and the display 151 may be mounted in the control portion.

Various electronic devices 184 are mounted on the main circuit board 185 to control the mobile terminal 100 and it may be arranged a predetermined portion of the mobile terminal. The electronic devices 184 include an AP (application process) chip configured to drive OS and various applications, GPU (graphic processing unit) and a power management chip.

When using the mobile terminal, such the electronic devices 184 are continuously operated and a lot of heat is generated. FIG. 4 is a diagram illustrating thermal gradient of a conventional mobile terminal. \textcircled{1} refers to the highest temperature and \textcircled{4} refers to the lowest temperature. As the number is getting higher, it means that the temperature is getting lower. The main circuit board 185 having the electronic devices 184 generating much heat mounted thereon is located in the predetermined portion of the mobile terminal 100, such that the temperature in the portion can be different from the temperature in the other portion.

The temperature of the mobile terminal 100 rises because of the heat concentrated on the portion and it has influence on the performance of the mobile terminal, such that the mobile terminal 100 may get too hot for the user to hold in the hand.

A stationary type terminal such as a computer may include a radiation fan configured to lower the temperature by flowing air near the main circuit board to sink the heat of the main circuit board. Considering the portability, it is difficult to use a cooling method using the radiation fan in the mobile terminal 100.

In the prior art the present invention pertains to, a heat radiating plate formed of a material having a high thermal conductivity is used in diffusing the heat according to a heat conduction method. Examples of such a heat radiating plate include a copper sheet and a graphite sheet. However, such a thermal conduction method has a limitation of deteriorated heat transfer efficiency, compared with a thermal convection method having a fluid transfer heat directly.

According to the present invention, a working fluid 210 is injected to the heat exchanger 200 having a plurality of micro-paths 201to use convection of the working fluid 210, such that the heat may be transferred to the heat generated portion to the other portion. Accordingly, the heat may be prevented from being concentrated on a specific portion of the mobile terminal and heat radiation performance may be enhanced. A side of the heat exchanger 200 is arranged in the high temperature portion of the mobile terminal and the other side of the heat exchanger 200 is arranged in the relatively low temperature portion of the mobile terminal, such that the micro-paths may be extended from the side to the other side.

As shown in FIG. 3, the heat exchanger 200 may perform a function of a middle frame configured to support the display 151 from a back surface of the display 151 as well as the heat radiation function.

In the middle frame may be formed a supporting structure to support the display 151, the user input unit 131 and the main circuit board 185. The supporting structure includes a small embossing portion. An injection molded portion 230 having the small embossed portion may be integrally formed in a heat exchanging portion 220 having the paths in a double-injection molding method.

As shown in FIG. 3, the heat exchanger 200 functioned as the middle frame makes a conventional middle frame omitted. The number of members can be reduced more than the heat exchanger is additionally provided in the control portion and the thickness of the mobile terminal can be prevented from increasing.

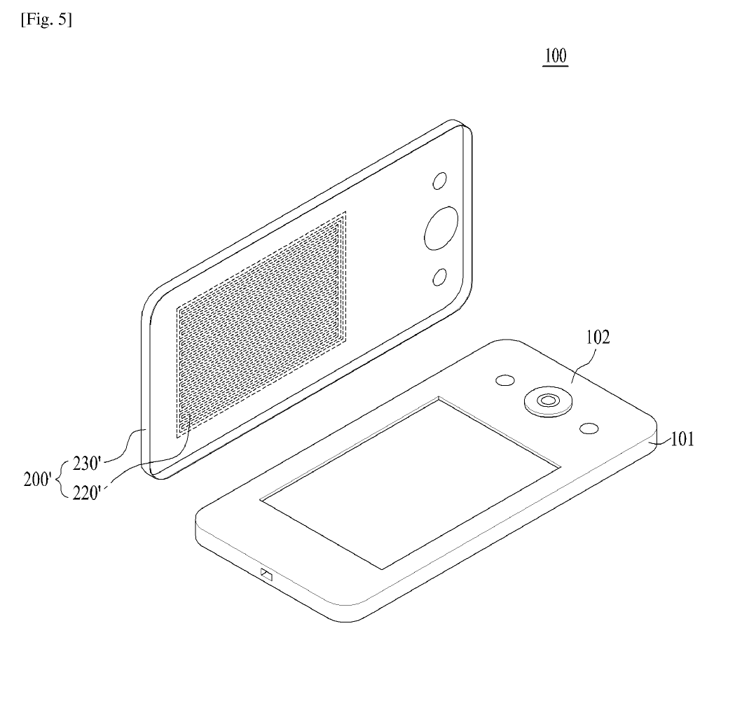

FIG. 5 shows a heat exchanger 200 functioned as a back cover according to another embodiment. A back cover may be concavely recessed and a heat exchanging portion 220 may be inserted in the recessed portion. Alternatively, similar to the middle frame, an injection molded portion 230 is double-injection molded in the heat exchanging portion 220 having paths in a back cover shape and an external surface of the heat exchanger is covered by a finishing material. Accordingly, the heat exchanger 200 functioned as the back cover may be provided.

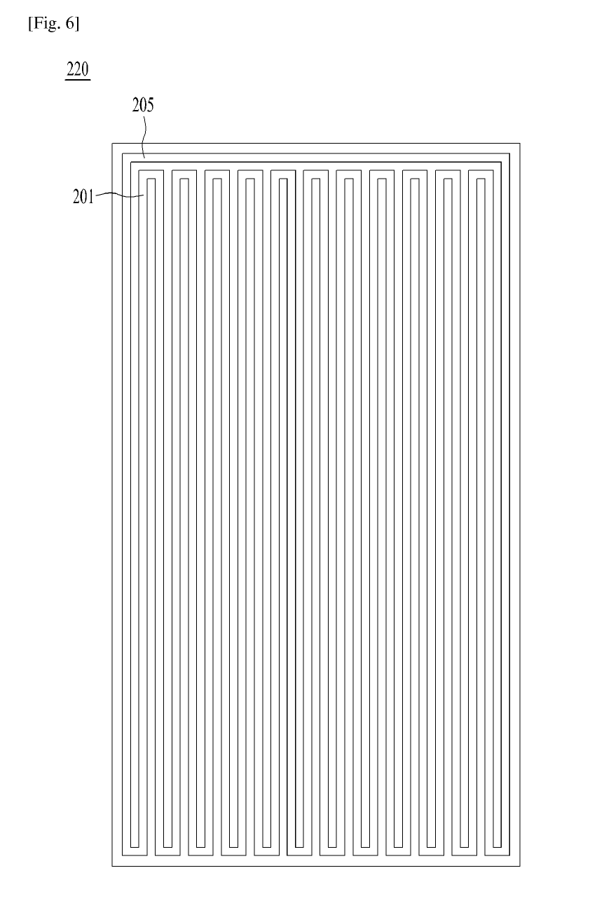

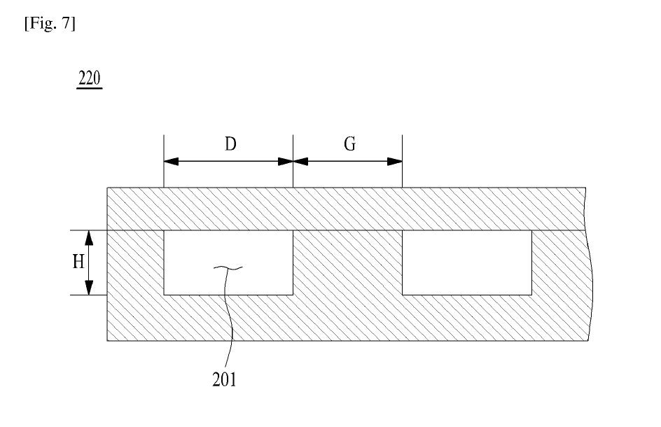

FIG. 6 is a longitudinal sectional diagram of the heat exchanger according to one embodiment of the present invention. FIG. 7 is a horizontal sectional diagram of the heat exchanger according to one embodiment of the present invention. The heat exchanger 220 includes the plurality of the micro-paths 201 extended from a direction to the other opposite direction (in the drawing, a vertical direction). The working fluid 210 is filled in the micro-paths and the working fluid generates phase-change according to ambient temperatures. The working fluid 210 is flowing with alternating a liquid state 211 and a gaseous state 212.

Such the heat exchanger having the working fluid 210 that vibrates and fluids in the liquid state and the gaseous state alternatively to generate the phase change is called as Pulsating Heat Pipe (PHP). According to the present invention, the size of the pulsating heat pipe is reduced and a micro PHP having micro-sized paths is provided in the mobile terminal according to the present invention.

At this time, the size of each micro-path cannot be the same and the thickness of each micro-path can be varied.

The heat exchanger 220 includes an evaporator (A) arranged in a portion and a condenser (C) arranged in the other opposite portion and a bubble/slug oscillation (B) arranged between the evaporator (A) and the condenser (C). The heat is absorbed and phase-changed into a gaseous state in the evaporator (A). The gaseous state heat is flowing to the condenser (C) while phase-changed in the bubble/slug oscillation (B). The condenser (C) emits the heat and re-generates phase-change into a liquid state. The liquidized working fluid 210 flows to the evaporator (A) again.

The evaporator (A) is positioned in the highest temperature portion of the mobile terminal and the condenser (C) is positioned in the lowest temperature portion of the mobile terminal. The working fluid 210 is lighter in the gaseous state 212 than in the liquid state 211 and it has a property of moving in an opposite direction of the gravity. Accordingly, to make the heat exchanging performed more actively, the evaporator (A) may be positioned in a lower portion of the mobile terminal 100 and the condenser (C) may be positioned in an upper portion of the mobile terminal 100.

When the main circuit board 185 is arranged in the lower portion of the mobile terminal 100 as shown in FIG. 3, the heat exchanger 200 can be arranged with the evaporator (A) arranged in the lower portion of the mobile terminal 100 and the condenser positioned in the upper portion of the mobile terminal.

The micro-paths may be longitudinally formed from one side toward the other side to penetrate the evaporator (A), the bubble/slug oscillation (B) and the condenser (C). Each of the micro-paths 201 is connected to a neighboring path 201, to have a serpentine curved structure. Both ends of the 4-line-structured micro path are connected by a connection path 205 and such a connection path 205 may form a closed loop type path. In the drawing, the paths form one closed loop. However, the paths may form a plurality of closed loops.

In case of forming the closed loop, the working fluid can circulate along the closed loop. Here, even if the micro-paths form the closed loop, the working fluid are not necessarily flowing along one direction and it is partially oscillating and flowing from one direction to the other direction, with alternating the gaseous state and the liquid state.

The micro-paths 201 are formed by etching a metallic plate such as a steel use stainless (SUS). Alternatively, micro-paths are formed in a laser etching method and a metallic plate is disposed on the micro-paths, only to form the heat exchanger 200. When the micro-paths 201 are formed in a square shape as shown in FIG. 7, the thickness per unit area can be reduced in comparison with circular shaped micro-paths 201. When forming the micro-paths 201 in the etching method, it is easier to fabricate the square shaped micro-paths than the circular shaped micro-paths.

The size of the path 201 may be several mm or hundreds of μm. A hydraulic diameter means a diameter of the converted path when an area of a rectangular micro-path 201 is converted into an area of a circular micro-path. The hydraulic diameter is a double value gained by multiplying a value gained by multiplying two sides (D and H) of the rectangular micro-path is divided by a value gained by adding the two sides (D and H).

In other words, the hydraulic diameter (Dh) is 2(D×H)/(D+H). the micro-path having a hydraulic diameter of 500 μm or more can be provided. The optimized hydraulic diameter can be varied based on a boiling point and a viscosity point of a solvent.

A following [Table 1] refers standards of various heat exchanger samples by differentiating channel diameters and hydraulic diameters of the micro-paths 201 formed in heat exchangers 200 having one size, to derive the optimized size of the micro-path.

[Table 1]

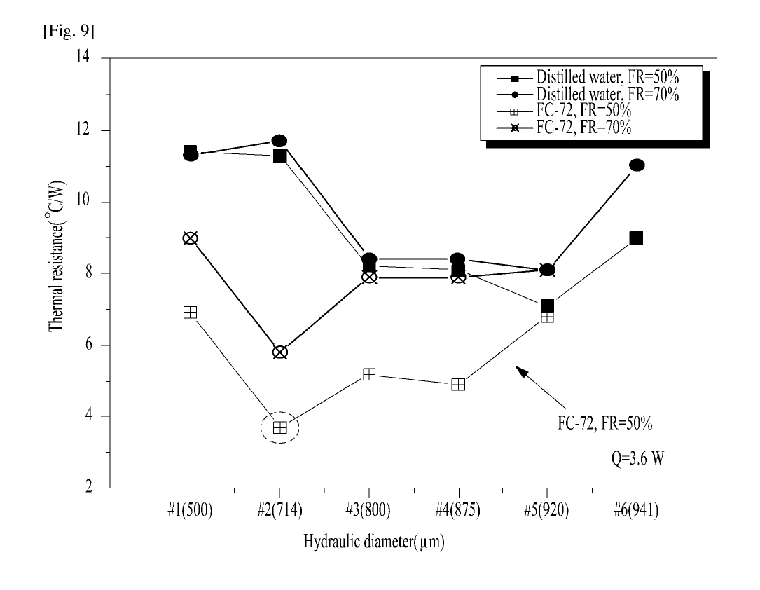

FIG. 9 is a graph illustrating thermal resistance based on the size of a micro-path provided in the heat exchanger, a type of a working fluid and an injection degree of the working fluid according to one embodiment of the present invention, based on the heat pipe samples shown in [Table 1]. Thermal resistance is an index showing whether heat is transferred well and it refers to a temperature difference between one point where the same amount of heat is applied and another point distant from the point. As the thermal resistance is getting lower, heat transfer efficiency is getting higher and it means that heat radiating performance is good.

Referring to FIG. 9, when the working fluid 210 is FC-72, the heat pipe 200 having a hydraulic diameter of 714 μm has the best heat radiation efficiency. When the working fluid 210 is water, the heat pipe having a hydraulic diameter of 920 μm has the best heat radiation efficiency.

It is not sure that the gap (G) between the paths 201 is closely related to the actual performance. If the gap between the paths 201 is too wide, the overall area of the micro-paths 201 might be reduced. If it is too narrow, the paths cannot be coupled to the metallic plate disposed on the micro-paths 201 stably. Considering those problems, the gap may be formed in a proper size, for example, approximately 1 mm.

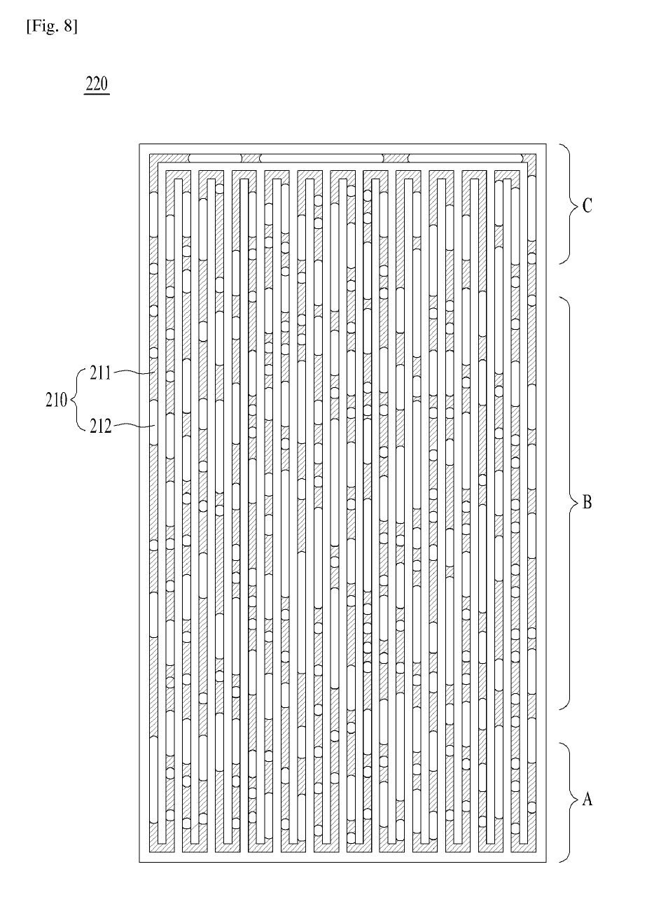

FIG. 8 is a sectional diagram illustrating that a working fluid 210 filled in the heat exchanging portion 220 according to one embodiment of the present invention is flowing. When the working fluid 210 is inserted in the micro-paths, the micro-paths are partially filled with the working fluid and the other empty space is made vacuum or lower-pressured.

When absorbing heat, the working fluid 210 may be evaporated and it is preferred that the working fluid has a low boiling point. When using the working fluid having a boiling point of 40° C. to 70° C. under the atmospheric pressure, such a boiling point is lowered under a vacuum or low-pressured state. Then, the working fluid 210 can be changed into a gaseous state when the mobile terminal 100 is driven.

It is preferred that perfluorocarbon compounds (PFCs) having a relatively lower boiling point than water having a relatively high boiling point. PFC compounds are non-toxic and have little evaporation heat, such that it can be phase-changed easily into a gaseous state.

Based on experiments, the working fluid 210 is FC-72 manufactured by 3M and it has a boiling point of 56° C. The working fluid 210 can be gasified approximately at 40° C. in a vacuum state. As shown in FIG. 9, FC-72 has better efficiency than water.

The liquid state working fluid 210 absorbs the heat and evaporated into the gaseous state and emits the heat. After that, the temperature of the working fluid 210 is lowered and phase-changed into a liquid state. The working fluid 212 evaporated after absorbing the heat may not absorb heat and it is lighter than the liquid state working state 211, to flow in the opposite direction of the gravity. At this time, when the micro-paths 201 are connected to each other, the working fluid 210 filed in the micro-paths 201 repeats the expansion and contraction and the gasification and liquefaction and generates a force of pushing each other.

If a small amount of working fluid 210 is injected, the effect of pushing the working fluid by the expansion could be decreased and a circulation speed of the working fluid 210 might be deteriorated disadvantageously. In contrast, if the micro-paths are filled with the working fluid 210, there is an insufficient space where the working fluid has to be expanded and efficient convection could not be generated. Because of that, the micro-paths could be overheated and the heat exchanger 200 might be damaged.

Accordingly, more than 30% and 70% or less of the working fluid 210 may be injected and an injection rate of the working fluid 210 can be variable according to the types of the working fluid 210. When FC-72 is used as the working fluid 210 based on experiments as shown in FIG. 9, it is shown that injecting 50% of FC-72 has the best efficiency. The micro-paths are partially filled with the working fluid 210 injected therein and the other space of the micro-paths is made vacuum. To make the other space of the micro-paths vacuum, the air inside the paths may be absorbed or a liquid may be injected in a vacuum or low-pressured chamber.

As shown in FIG. 8, the injected working fluid 210 absorbs heat in the evaporator

(A) and the volume of the working fluid is increased. Also, the phase of the working fluid is changed and vapors 212 are formed. The size of the vapor 212 is increasing longitudinally as the working fluid is absorbing the heat more and more, and then the vapors are flowing to the condenser (C). The working fluid 211 liquidized by emitting the heat and small-sized in the condenser (C) may flow to the evaporator (A) along the micro-paths 201.

As mentioned above, a gas is lighter than a liquid and has a property of moving in the opposite direction of the gravity. The micro-paths 201 may be formed in upward/downward direction and electronic components generating much heat may be arranged in a gravity direction (a downward direction), for example, the main circuit board 185.

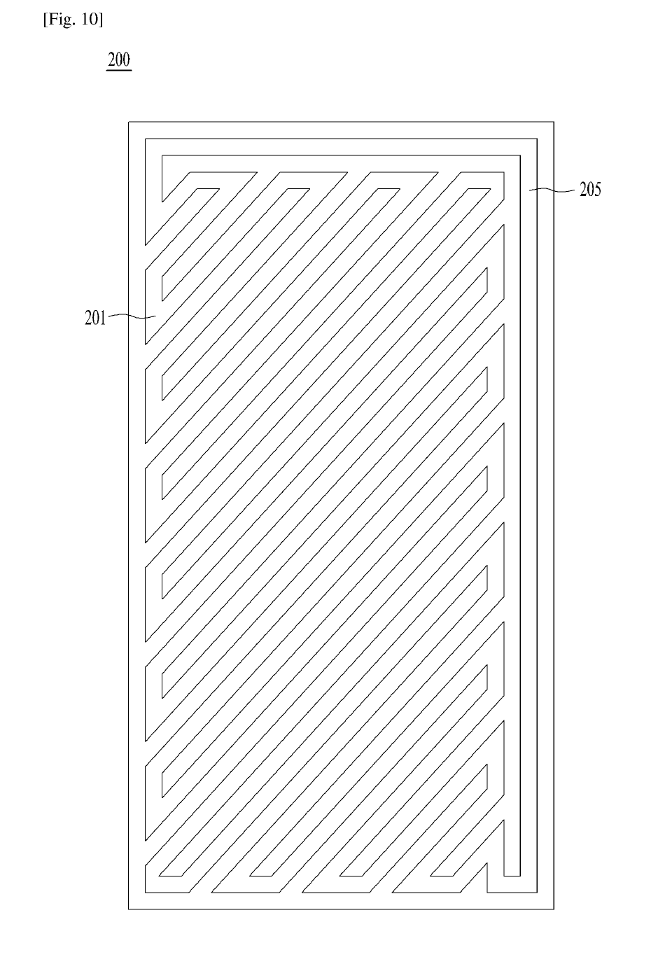

When the user uses the mobile terminal 100, with holding it in a horizontal direction, the speed of the gaseous working fluid 210 flowing along the micro-paths 201 the might be decreased. As shown in FIG. 10, the micro-paths 201 may be obliquely formed in a diagonal direction the working fluid 210 may flow even in case the user holds the mobile terminal in the hand in a horizontal direction.

Moreover, the mobile terminal 100 according to the present invention may further include an oscillator 186. The oscillator 186 is a device that generates vibration in the mobile terminal 100 for an alarm function and the like. When the oscillator 186 is driven, the flow of the working fluid 210 is activated fast in the heat exchanger 100.

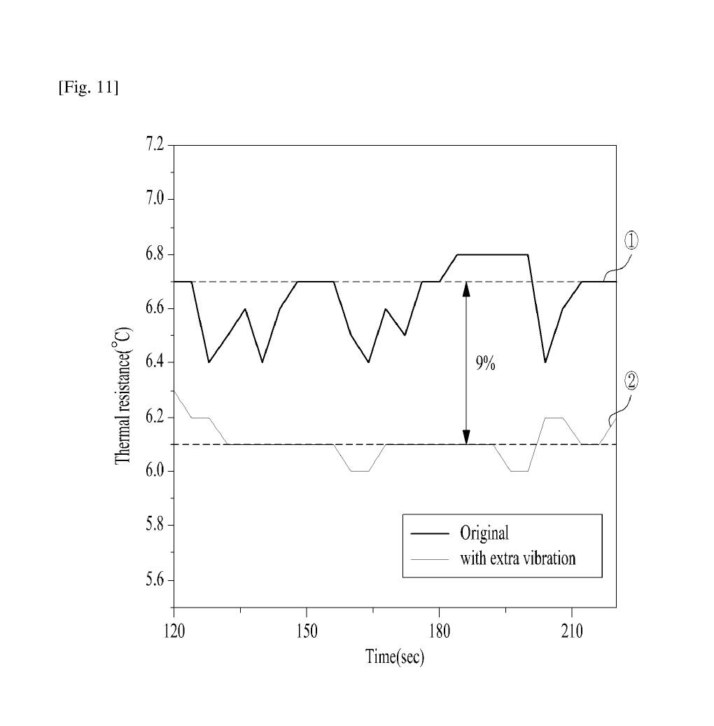

FIG. 11 is a graph illustrating thermal resistance based on whether to use an oscillator 186 of the mobile terminal 100 according to the embodiment of the present invention. Thermal resistance is lowered more by 9% and heat radiation efficiency is deteriorated in case of using the oscillator 186 \textcircled{2} than in case of not using the oscillator 186.

The oscillator 186 may be driven when the temperature of the mobile terminal rises higher than the operation temperature of the heat exchanger 200. The operation temperature of the heat exchanger 200 refers to the temperature at which the vibration of the working fluid 210 starts once the evaporation of the working fluid starts. when the temperature of the mobile terminal reaches 25° C. to 30° C., the working fluid 210 starts to vibrate and the oscillator 196 may be set to operate in that range of temperatures.

Also, when the oscillator 186 is continuously vibrated, the user could feel uncomfortable. Accordingly, the oscillator 186 may be controlled to drive intermittently or the user can control the driving of the oscillator 186 freely.

According to at least one embodiments of the present invention, the mobile terminal 100 including the heat exchanger 200 may use a convection method instead of the conventional conduction type heat radiation method and enhance the heat radiation efficiency. The heat exchanger 200 including the micro-paths 201 having the hydraulic diameter of approximately 700 μm may be provided. When injecting 50% of FC-72 as the working fluid 210, the thermal resistance can be lowered by approximately 50%, compared with the graphite sheet. Accordingly, the heat radiation efficiency can be increased by approximately 150% or more.

Furthermore, the heat exchanger may be functioned as the middle frame configured to support the display as well as the heat radiating function. When using the heat exchanger according to the present invention, instead of the middle frame, the heat radiation efficiency may be enhanced, without increasing the number of components.

When a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A mobile terminal comprising:
a case comprising a control portion provided therein;
a display coupled to the case;
a main circuit board mounted in a predetermined portion of the control portion;
a heat exchanger having a portion arranged adjacent to the main circuit board, with a plurality of micro-paths extended from the portion to the other portion, each of the micro-paths connected to a neighboring one to form a closed loop; and
a working fluid configured to absorb heat in the portion and emit the heat in the other portion, to be liquefied, the working fluid configured to vibrate along the micro-paths,
wherein gaseous state working fluid and liquid state working fluid are mixed intermittently.

2. The mobile terminal according to claim 1, wherein the heat exchanger is a middle frame configured to support a back surface of the display.

3. The mobile terminal according to claim 1, wherein the heat exchanger is a back cover detachably coupled to a back surface of the case.

4. The mobile terminal according to claim 1, wherein the heat exchanger is comprising:
a heat exchanging portion where the micro-paths are formed; and
an injection molded portion coupled to the heat exchanging portion in a double injection molding method.

5. The mobile terminal according to claim 1, wherein the micro-paths form a serpentine structure, and
further comprising a connection path configured to connect both ends of the serpentine structure.

6. The mobile terminal according to claim 1, wherein the portion is a lower portion of the mobile terminal and the other portion is an upper portion of the mobile terminal, and
the micro-paths are formed in a vertical direction.

7. The mobile terminal according to claim 1, wherein the micro-paths are obliquely formed in a diagonal direction with respect to the mobile terminal.

8. The mobile terminal according to claim 1, wherein a cross section of a micro-path is rectangular.

9. The mobile terminal according to claim 1, wherein a hydraulic diameter of the micro-path is 500 μm or more and 1000 μm or less.

10. The mobile terminal according to claim 1, wherein the working fluid is injected in the micro-paths by 30% or more and 70% or more of the volume.

11. The mobile terminal according to claim 1, wherein a boiling point of the working fluid is 40° C. or more and 70° C. or less.

12. The mobile terminal according to claim 1, wherein the working fluid is perfluorocarbon (PFCs) compound.

13. The mobile terminal according to claim 1, further comprising:
a oscillator configured to apply vibration to the heat exchanger,
wherein the oscillator is driven when the temperature of the mobile terminal is an operation temperature of the heat exchanger or more.

14. The mobile terminal according to claim 13, wherein the oscillator is driven at predetermined intervals intermittently.
